(19) United States
(12) Patent Application Publication
(10) Pub. No.: US 2023/0309292 A1
(43) Pub. Date: Sep. 28, 2023

(54) CAPACITOR AND DRAM DEVICE INCLUDING THE SAME

(71) Applicant: Samsung Electronics Co., Ltd., Suwon-si (KR)

(72) Inventors: Sanghyuck AHN, Suwon-si (KR); Jungoo Kang, Suwon-si (KR); Dayeon Nam, Suwon-si (KR); Juwon Park, Suwon-si (KR); Donggeon Lee, Suwon-si (KR)

(73) Assignee: Samsung Electronics Co., Ltd., Suwon-si (KR)

(21) Appl. No.: 18/164,287

(22) Filed: Feb. 3, 2023

(30) Foreign Application Priority Data
Mar. 22, 2022 (KR) 10-2022-0035144

(51) Int. Cl. H10B 12/00

(52) U.S. Cl. CPC H10B 12/315; H10B 12/033

(57) ABSTRACT

A capacitor includes a first lower electrode pattern including a first material including a metal, and a second lower electrode pattern including a second material different from the first material, wherein the first material and the second material are exposed on an outer sidewall of a lower electrode structure having a pillar shape. The capacitor includes a dielectric layer on the lower electrode structure, and an upper electrode on the dielectric layer.

### CROSS-REFERENCE TO RELATED APPLICATION

This application claims priority under 35 USC § 119 to Korean Patent Application No. 10-2022-0035144, filed on Mar. 22, 2022, in the Korean Intellectual Property Office (KIPO), the contents of which are incorporated by reference herein in their entirety.

### FIELD

Some example embodiments relate to capacitors and/or a DRAM device including the same.

### BACKGROUND

In a DRAM device, each of the memory cells may include a transistor and a cell capacitor. In order to increase a capacitance of the cell capacitor, a lower electrode in the cell capacitor may have a high aspect ratio. The lower electrode may be inclined or bent by stress, so that the lower electrode may include a material having a low bending stress.

### SUMMARY

Some example embodiments provide a capacitor having a high capacitance and a low bending defect in a lower electrode.

Some example embodiments provide a DRAM device including a capacitor having a high capacitance and a low bending defect in a lower electrode

According to some example embodiments, a capacitor includes a first lower electrode pattern including a first material including a metal, a second lower electrode pattern including a second material different from the first material, wherein the first material and the second material are exposed on an outer sidewall of a lower electrode structure having a pillar shape, a dielectric layer on the lower electrode structure, and an upper electrode on the dielectric layer.

According to some example embodiments, a capacitor includes a lower electrode structure including a first material, a second material, a first lower electrode pattern, a second lower electrode pattern, and a third lower electrode pattern, wherein the second material is different from the first material, the first material and the second material are exposed on an outer sidewall, and the lower electrode structure has a pillar shape. The capacitor includes a dielectric layer on the lower electrode structure, and an upper electrode on the dielectric layer, wherein the first lower electrode pattern includes the first material, and the first lower electrode pattern has a pillar shape, wherein the second lower electrode pattern includes the second material, the second lower electrode pattern is on an upper surface of the first lower electrode pattern, and the second lower electrode pattern has a cylindrical shape, and wherein the third lower electrode pattern includes the first material, the third lower electrode pattern is on the second lower electrode pattern, and the third lower electrode pattern fills an inner portion of the second lower electrode pattern.

According to some example embodiments, a DRAM device includes a cell transistor on a substrate, the cell transistor including a gate structure, a first impurity region, and a second impurity region, a bit line structure electrically connected to the first impurity region, and a cell capacitor disposed on the bit line structure. The cell capacitor is electrically connected to the second impurity region, wherein the cell capacitor includes a lower electrode structure including a first lower electrode pattern and a second lower electrode pattern, the cell capacitor includes a dielectric layer on the lower electrode structure, and the cell capacitor includes an upper electrode on the dielectric layer, and wherein the second lower electrode pattern includes a material having a bending stress greater than a bending strength of the first lower electrode pattern, and wherein at least a portion of the first lower electrode pattern and the second lower electrode pattern is exposed on an outer wall of the lower electrode structure.

In the capacitor according to some example embodiments, at least two materials may be exposed on an outer sidewall of the lower electrode structure, so that defects due to bending stress in the lower electrode structure may be decreased, and a capacitance of the capacitor may be increased.

### BRIEF DESCRIPTION OF THE DRAWINGS

Some example embodiments will be more clearly understood from the following detailed description taken in conjunction with the accompanying drawings. FIGS. 1 to 37 represent non-limiting, example embodiments as described herein.

FIG. 1 is a cross-sectional view illustrating a capacitor in accordance with some example embodiments;

FIG. 2 is a cross-sectional view illustrating a capacitor in accordance with some example embodiments

FIG. 3 is a cross-sectional view illustrating a capacitor in accordance with example embodiments;

FIGS. 4, 5, 6, 7, 8, 9, 10, 11, 12 and 13 are cross-sectional views illustrating a method of manufacturing a semiconductor device according to some example embodiments;

FIGS. 14 and 15 are cross-sectional views illustrating a method of manufacturing the capacitor of FIG. 3 according to some example embodiments;

FIG. 16 is a cross-sectional view illustrating a capacitor in accordance with some example embodiments;

FIG. 17 is a cross-sectional view illustrating a capacitor in accordance with some example embodiments;

FIG. 18 is a cross-sectional view illustrating a capacitor in accordance with some example embodiments;

FIG. 19 is a cross-sectional view illustrating a capacitor in accordance with some example embodiments;

FIG. 20 is a cross-sectional view illustrating a capacitor according to some example embodiments;

FIGS. 21, 22, 23 and 24 are cross-sectional views for illustrating a method of manufacturing the capacitor of FIG. 17 in accordance with some example embodiments;

FIGS. 25, 26, 27 and 28 are cross-sectional views for illustrating a method of manufacturing the capacitor of FIG. 18 in accordance with some example embodiments;

FIG. 29 is a cross-sectional view for illustrating a method of manufacturing the capacitor of FIG. 19 in accordance with some example embodiments;

FIG. 30 is a cross-sectional view for illustrating a method of manufacturing the capacitor of FIG. 20 in accordance with some example embodiments;

FIG. 31 is a plan view illustrating a layout of a DRAM device in accordance with some example embodiments;

FIG. 32 is a cross-sectional view of a DRAM device in accordance with some example embodiments; and

FIGS. 33 to 37 are cross-sectional views for illustrating a method of manufacturing a capacitor in accordance with some example embodiments.

### DETAILED DESCRIPTION

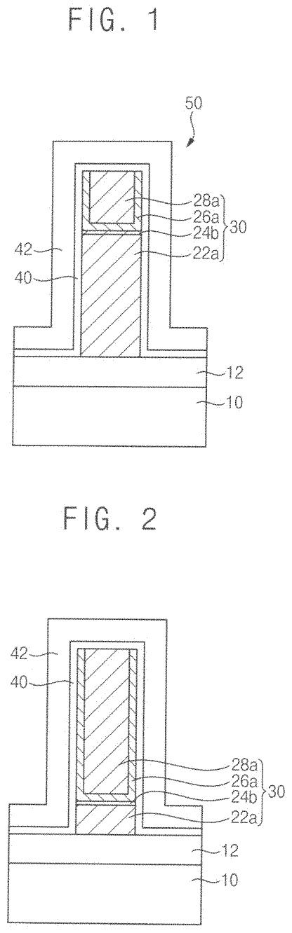

FIG. 1 is a cross-sectional view illustrating a capacitor in accordance with some example embodiments. FIG. 2 is a cross-sectional view illustrating a capacitor in accordance with some example embodiments.

Referring to FIG. 1, a capacitor 50 may include a lower electrode structure 30, a dielectric layer 40, and an upper electrode 42.

In some example embodiments, the capacitor 50 may be formed on a lower structure 12 formed on a substrate 10. Although not shown, the lower structure 12 may include a transistor, a contact, a conductive line, and an insulating interlayer covering them, etc.

The lower electrode structure 30 formed on the lower structure 12. The lower electrode structure 30 may have a pillar shape. That is, the lower electrode structure 30 may have a cylinder shape with filled an inner portion. The lower electrode structure 30 may include at least two materials, and at least two materials may be exposed on an outer wall of the lower electrode structure 30. The materials included in the lower electrode structure 30 may include metal, and thus least two metals may be included in the lower electrode structure 30.

In some example embodiments, the lower electrode structure 30 may include a first material and a second material different from the first material.

The first material may be a main material occupying most of an inner portion of a pillar in the lower electrode structure 30. Therefore, in the lower electrode structure 30, a content of the first material may be greater than a content of the second material, and a volume of the first material may be greater than a volume of the second material. The first material may include a metal or a metal nitride having a bending stress lower than a bending stress of the second material.

In some example embodiments, the first material may include titanium nitride (TiN) or titanium (Ti), but example embodiments are not limited thereto. As the first material is included in the lower electrode structure 30, a bending of the lower electrode structure 30 may be decreased.

The second material may be locally formed on an outer sidewall of the pillar in the lower electrode structure 30. The second material may include a material to increase a capacitance of the capacitor 50. When the second material is used as the lower electrode, the capacitance of the capacitor may increase compared to a case where the first material is used as the lower electrode. The second material may have excellent reactivity and excellent adhesion properties with the dielectric layer 40 subsequently formed. Therefore, the capacitance of the capacitor having the second material used as the lower electrode may be higher than a capacitance of the capacitor having the first material used as the lower electrode. Thus, the capacitance at a contacting portion of the second material and the dielectric layer may be higher than the capacitance at a contacting portion of the first material and the dielectric layer.

However, the second material may have a bending stress higher than a bending stress of the first material. When the content of the second material included in the lower electrode structure 30 is increased, a bending defect may occur. Therefore, in the lower electrode structure 30, the content of the first material may be greater than the content of the second material, and the volume of the first material may be greater than the volume of the second material.

In some example embodiments, the second material may include niobium nitride, niobium, indium tin oxide (ITO), ruthenium (Ru), or the like. As the second material is exposed on sidewalls of the lower electrode structure, the capacitance of the capacitor may be increased.

In some example embodiments, the lower electrode structure 30 may include a first lower electrode pattern 22a including the first material, a seed layer pattern 24b, a second lower electrode pattern 26a including the second material, and a third lower electrode pattern 28a including the first material. The seed layer pattern 24b may include a metal nitride. For example, the seed layer pattern 24b may have a material the same or substantially the same as a material of the first lower electrode pattern 22a. In some example embodiments, the seed layer pattern 24b and the first lower electrode pattern 22a may be merged into one pattern.

In order to form the lower electrode structure 30, first, a mold layer (not shown) may be formed and a hole may be formed in the mold layer. The lower electrode structure 30 may be formed in the hole of the mold layer, so that the lower electrode structure 30 may have a shape the same or substantially the same as an inner space of the hole. The mold layer may be removed after forming the lower electrode structure 30, so that the capacitor 50 may not include the mold layer.

For example, as shown in FIG. 1, in the lower electrode structure 30, the first lower electrode pattern 22a may fill a lower portion and a middle portion of the hole. The first lower electrode pattern 22a may have a pillar shape. The seed layer pattern 24b may be formed on the first lower electrode pattern 22a. The second lower electrode pattern 26a may be formed along an upper sidewall of the hole and an upper surface of the seed layer pattern 24b, and the second lower electrode pattern 26a may have a cylindrical shape. The third lower electrode pattern 28a may be formed on the second lower electrode pattern 26a, and may fill an inner portion (e.g., inner space) of the second lower electrode pattern 26a. The third lower electrode pattern 28a may have a pillar shape.

Accordingly, the first lower electrode pattern 22a and the second lower electrode pattern 26a may be exposed on the outer wall of the lower electrode structure 30. That is, in the lower electrode structure 30, the first material and the second material may be exposed. Particularly, the second lower electrode pattern 26a including the second material may be exposed on an upper outer wall of the lower electrode structure 30.

For example, as shown in FIG. 2, in the lower electrode structure 30, the first lower electrode pattern 22a may fill a lower portion of the hole. In some example embodiments, as the second lower electrode pattern 26a is formed along middle and upper sidewalls of the hole and an upper surface of the first lower electrode pattern, a height (e.g., cylinder height) of the second lower electrode pattern 26a having a cylindrical shape may be increased. Thus, a height of the first lower electrode pattern 22a and the height of the second lower electrode pattern 26a may be controlled. As the height of the second lower electrode pattern 26a increases, an area of the second lower electrode pattern 26a exposed on the outer wall of the lower electrode structure 30 may increase. Accordingly, the capacitance of the capacitor 50 may increase. As the height of the second lower electrode pattern 26a increases, the height of the third lower electrode pattern 28a may also increase.

The second lower electrode pattern 26a including the second material may be locally formed at a position where bending defects hardly occur in the lower electrode structure 30, but the position of the second lower electrode pattern 26a is not limited thereto. That is, the position of the second lower electrode pattern 26a including the second material may be variously changed.

The lower electrode structure 30 may have a sidewall profile the same as an inner sidewall profile of the hole. Accordingly, the sidewall of the lower electrode structure 30 may not have a laterally protruding portion or recessed portion. For example, the sidewall of the lower electrode structure 30 may not protrude at a position for forming the second lower electrode pattern 26a. Also, an inner width (e.g., a diameter) of the third lower electrode pattern 28a may be less than an inner width of the first lower electrode pattern 22a.

In some example embodiments, a support pattern (not shown) for supporting the lower electrode structure 30 may be further formed on a portion of an outer wall of the lower electrode structure 30. The support pattern may be connected with adjacent lower electrode structures 30 to each other. The support pattern may include an insulation material.

The dielectric layer 40 may be conformally formed along an outer surface of the lower electrode structure 30. The dielectric layer 40 may contact the first material and the second material exposed on the outer wall of the lower electrode structure 30, respectively.

The dielectric layer 40 may include a metal oxide having a high dielectric constant, e.g., HfO2, ZrO2, TiO2, TaO2, or La2O3, but example embodiments are not limited thereto. That is, the dielectric layer 40 may include a single metal oxide or may have a structure in which a plurality of metal oxides are stacked. For example, the dielectric layer 40 may include hafnium oxide (HfO2).

When the support pattern is formed on the lower electrode structure 30, the dielectric layer 40 may also be formed on the support pattern.

The upper electrode 42 may include, e.g., titanium nitride (TiN), titanium (Ti), tantalum (Ta), tantalum nitride (TaN), ruthenium (Ru), tungsten, tungsten nitride, Nb, NbN, indium tin oxide (ITO), Ta doped SnO2, Nb doped SnO2, Sb doped SnO2, or V doped SnO2, etc., but example embodiments are not limited thereto.

As described above, as the first material is included in the lower electrode structure, the bending defect of the lower electrode structure may be decreased. In addition, as the second material is locally included at the outer wall of the lower electrode structure, the capacitance of the capacitor may be increased.

Capacitors having the lower electrode structure including the first material and the second material may have various structures. Hereinafter, some example embodiments of the capacitor including the lower electrode structure including the first material and the second material are described.

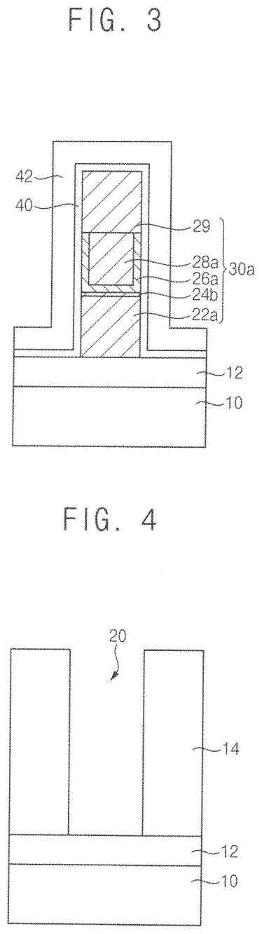

FIG. 3 is a cross-sectional view illustrating a capacitor in accordance with some example embodiments.

The capacitor shown in FIG. 3 may be the same or substantially the same as the capacitor shown in FIGS. 1 and 2, except for the lower electrode structure. Therefore, duplicate descriptions are omitted and only the lower electrode structure is mainly described.

Referring to FIG. 3, the lower electrode structure 30a may include a first lower electrode pattern 22a including the first material, a seed layer pattern 24b, a second lower electrode pattern 26a including the second material, a third lower electrode pattern 28a including the first material, and a fourth lower electrode pattern 29 including the first material. As the third and fourth lower electrode patterns 28a and 29 include the same material, the third and fourth lower electrode patterns 28a and 29 may be merged into one electrode pattern. Each of the first and second materials may be the same as described with reference to FIGS. 1 and 2.

The seed layer pattern 24b may include a metal nitride. For example, the seed layer pattern 24b may have a material the same as a material of the first lower electrode pattern 22a. In some example embodiments, the seed layer pattern 24b and the first lower electrode pattern 22a may be merged into one pattern.

The first lower electrode pattern 22a may fill a lower portion of the hole in the mold layer. The first lower electrode pattern 22a may have a pillar shape. The second lower electrode pattern 26a may be formed along an upper surface of the seed layer pattern 24b and a sidewall of a middle portion of the hole, and thus the second lower electrode pattern 26a may have a cylindrical shape. The second lower electrode pattern 26a may not extend to an uppermost sidewall of the hole. Accordingly, the second lower electrode pattern 26a may be positioned at a middle portion of the lower electrode structure 30a. The third lower electrode pattern 28a may be formed on the second lower electrode pattern 26a, and may fill an inner portion of the second lower electrode pattern 26a. The fourth lower electrode pattern 29 may be formed on the third lower electrode pattern 28a and the second lower electrode pattern 26a, and may completely fill the hole. Accordingly, the first lower electrode pattern 22a, the second lower electrode pattern 26a, the third lower electrode pattern 28a, and the fourth lower electrode pattern 29 may be exposed on the outer wall of the lower electrode structure 30a. That is, the first material and the second material may be exposed on an outer wall of the lower electrode structure 30a. Particularly, the second lower electrode pattern 26a including the second material may be exposed on the sidewall of the middle portion of the lower electrode structure 30a.

The lower electrode structure 30a may have a sidewall profile the same as an inner sidewall profile of the hole. Accordingly, the sidewall of the lower electrode structure 30a may not have a laterally protruding portion or recessed portion. For example, the sidewall of the lower electrode structure 30 may not protrude at a position for forming the second lower electrode pattern 26a. Also, an inner width (e.g., a diameter) of the third lower electrode pattern 28a may be less than an inner width of the first lower electrode pattern 22a. An inner width of the third lower electrode pattern 28a may be less than an inner width of the fourth lower electrode pattern 29.

FIGS. 4 to 13 are cross-sectional views for illustrating a method of manufacturing a capacitor in accordance with some example embodiments.

Referring to FIG. 4, a lower structure 12 including lower circuits and an insulating interlayer covering the lower circuits may be formed on a substrate 10. The lower circuits may include, e.g., a transistor, a contact plug, and a conductive line, etc.

A mold layer 14 may be formed on the lower structure 12. A portion of the mold layer 14 may be etched to form a hole 20 passing through the mold layer 14.

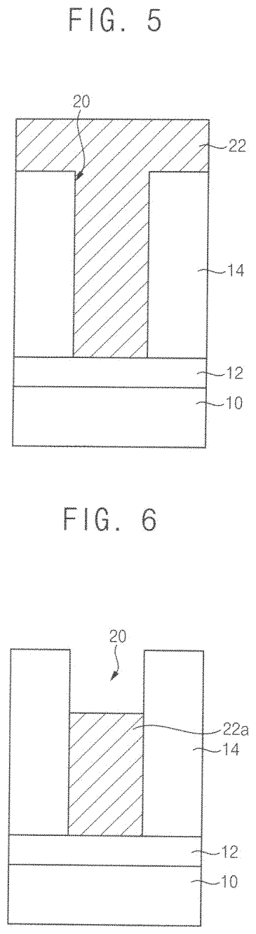

Referring to FIG. 5, a first lower electrode layer 22 may be formed on the mold layer to completely fill the hole 20. The first lower electrode layer 22 may include a first material. The first material may include a metal or a metal nitride having a low bending stress. In example embodiments, the first lower electrode layer 22 may include, e.g., titanium nitride (TiN) or titanium (Ti).

In example embodiments, the first lower electrode layer 22 may be formed by a physical vapor deposition (PVD), a chemical vapor deposition (CVD), or an atomic layer deposition (ALD) process.

Referring to FIG. 6, an upper portion of the first lower electrode layer 22 may be removed to form a first lower electrode pattern 22a in the hole 20. The removing process may include an etch back process.

In the removing process of the first lower electrode layer 22, the first lower electrode layer 22 formed on an upper surface of the mold layer 14 and an upper portion of the hole 20 may be removed to form the first lower electrode pattern 22a. The first lower electrode pattern 22a may fill a lower portion and a middle portion of the hole 20.

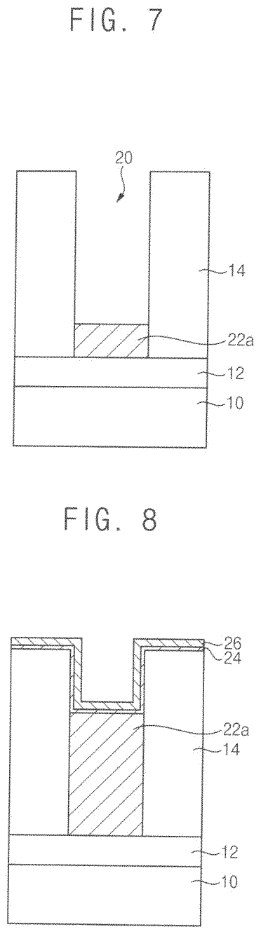

In some example embodiments, as shown in FIG. 7, in the removing process of the first lower electrode layer 22, the first lower electrode layer 22 formed on an upper surface of the mold layer 14 and upper and middle portions of the hole 20 may be removed to form the first lower electrode pattern 22a. The first lower electrode pattern 22a may have fill a lower portion of the hole 20. In some example embodiments, the capacitor shown in FIG. 2 may be manufactured by performing the subsequent processes in the same or substantially the same manner.

A position of the second lower electrode pattern may be controlled by adjusting a removing portion of the first lower electrode layer 22.

Referring to FIG. 8, a seed layer 24 may be conformally formed on a sidewall of the hole 20, an upper surface of the first lower electrode pattern 22a, and the mold layer 14. A second lower electrode layer 26 may be conformally formed on the seed layer 24.

In some example embodiments, the seed layer 24 may include a metal nitride. The second lower electrode layer 26 may be selectively deposited on only the seed layer by a selective deposition process.

For example, the seed layer 24 may include a material the same or substantially the same as a material of the first lower electrode pattern 22a. For example, the seed layer 24 may include titanium nitride (TiN). The seed layer 24 may serve as an adhesive layer for selectively depositing of the second lower electrode layer 26.

The second lower electrode layer 26 may have a thickness greater than a thickness of the seed layer 24. The second lower electrode layer 26 may include a second material different from the first material. When the second material is used as the lower electrode, a capacitance of the capacitor may increase compared to a case where the first material is used as the lower electrode. The second material may have a bending stress higher than the bending stress of the first material.

In some example embodiments, the second material may include, e.g., niobium nitride, niobium, indium tin oxide (ITO), and ruthenium (Ru), etc.

In some example embodiments, the second lower electrode layer 26 may be formed by an atomic layer deposition (ALD). The deposition process for forming the second lower electrode layer 26 may be performed at a temperature in a range of about 400° C. to about 650° C. When the deposition process of the second lower electrode layer 26 is performed at 400° C. or lower than 400° C., it is difficult to deposit the second lower electrode layer 26. When the second lower electrode layer 26 is deposited at a temperature of 650° C. or higher than 650° C., a thermal budget may be applied to a lower structure formed under the second lower electrode layer 26.

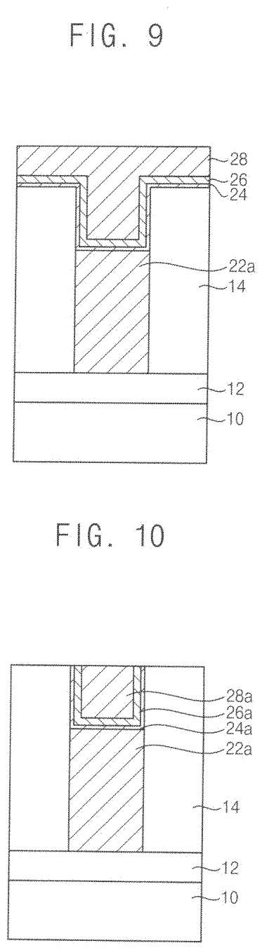

Referring to FIG. 9, a third lower electrode layer 28 may be formed on the second lower electrode layer 26 to completely fill the hole 20. The third lower electrode layer 28 may include the first material. In some example embodiments, the third lower electrode layer 28 may include, e.g., titanium nitride (TiN) or titanium (Ti).

Referring to FIG. 10, upper portions of the third lower electrode layer 28, the second lower electrode layer 26, and the seed layer 24 formed on the upper surface of the mold layer 14 may be removed by an etch back process to form a preliminary seed layer pattern 24a, a second lower electrode pattern 26a and a third lower electrode pattern 28a. The preliminary seed layer pattern 24a, the second lower electrode pattern 26a and the third lower electrode pattern 28a may be formed on the first lower electrode pattern 22a to fill the hole 20.

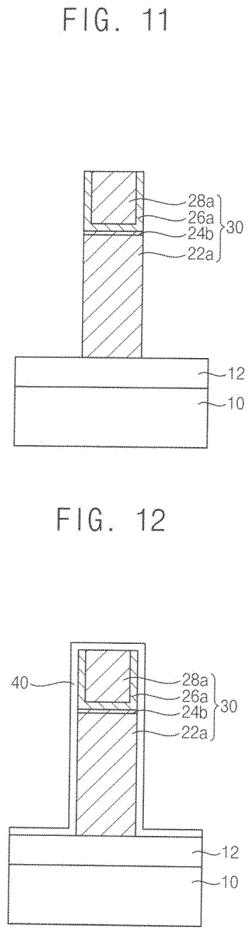

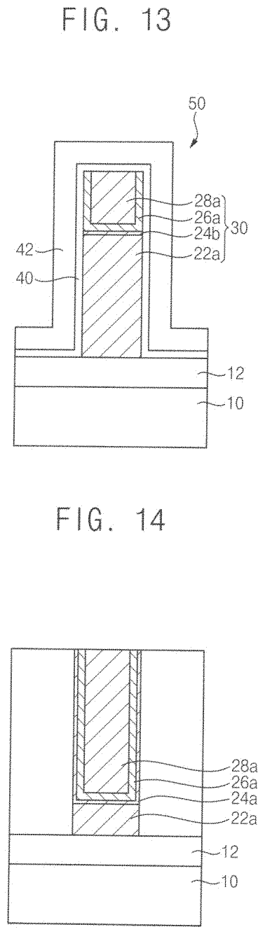

Referring to FIG. 11, the mold layer 14 may be removed. The removing process of the mold layer 14 may include an isotropic etching process.

In the removing process, the preliminary seed layer pattern 24a on a sidewall of the mold layer may be removed together, so that an outer wall of the second lower electrode pattern 26a may be exposed. In addition, in the removing process, a portion of the outer wall of the first lower electrode pattern 22a may be slightly removed.

Accordingly, a lower electrode structure 30 including the first lower electrode pattern 22a, a seed layer pattern 24b, the second lower electrode pattern 26a, and the third lower electrode pattern 28a may be formed. The first lower electrode pattern 22a and the second lower electrode pattern 26a may be exposed at an outer wall of the lower electrode structure 30.

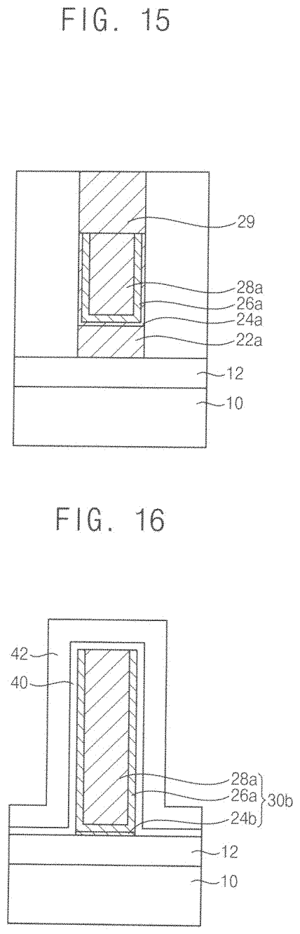

Referring to FIG. 12, a dielectric layer 40 may be formed on the sidewall and upper surface of the lower electrode structure 30 and the lower structure 12 to have a uniform thickness. The dielectric layer 40 may include a metal oxide having a high dielectric constant. The dielectric layer may include, e.g., HfO2, ZrO2, TiO2, TaO, or La2O3, but example embodiments are not limited thereto.

In some example embodiments, the dielectric layer 40 may be formed by an atomic layer deposition process.

Referring to FIG. 13, an upper electrode 42 may be formed on the dielectric layer 40.

The upper electrode 42 may include, e.g., titanium nitride (TiN), titanium (Ti), tantalum (Ta), tantalum nitride (TaN), ruthenium (Ru), tungsten, tungsten nitride, Nb, NbN, indium tin oxide (ITO), Ta doped SnO2, Nb doped SnO2, Sb doped SnO2, or V doped SnO2, etc., but example embodiments are not limited thereto.

In some example embodiments, the upper electrode 42 may be deposited by a physical vapor deposition (PVD), a chemical vapor deposition (CVD), or an atomic layer deposition (ALD) process.

The capacitor shown in FIG. 1 may be manufactured by performing the above process.

FIGS. 14 and 15 are cross-sectional views for illustrating a method of manufacturing a capacitor in accordance with some example embodiments.

Hereinafter, a method of manufacturing the capacitor shown in FIG. 3 is described.

First, the process described with reference to FIGS. 4 and 5 may be performed. Thereafter, the first lower electrode pattern 22a may be formed to fill a lower portion of the hole included in the mold layer by performing the process described with reference to FIG. 7.

Referring to FIG. 14, a seed layer may be conformally formed on the upper sidewall of the hole 20 and surfaces of the first lower electrode pattern 22a and the mold layer 14. A second lower electrode layer may be conformally formed on the seed layer. A third lower electrode layer may be formed on the second lower electrode layer to completely fill the hole 20.

Thereafter, the third lower electrode layer, the second lower electrode layer and the seed layer formed on an upper surface of the mold layer 14 may be removed by an etch back process. Accordingly, a preliminary seed layer pattern 24a, a second lower electrode pattern 26a and a third lower electrode pattern 28a may be formed on the first lower electrode pattern 22a to fill the hole 20.

The process described above may be substantially the same or substantially the same as that described with reference to FIGS. 8 to 10.

Referring to FIG. 15, the preliminary seed layer pattern 24a, the second lower electrode pattern 26a and the third lower electrode pattern 28a formed at an upper portion of the hole 20 may be removed. The removing process may include an etch back process. Accordingly, the preliminary seed layer pattern 24a, the second lower electrode pattern 26a, and the third lower electrode pattern 28a may be formed in a middle portion of the hole 20.

Next, a fourth lower electrode layer may be formed on the mold layer 14, the preliminary seed layer pattern 24a, the second lower electrode pattern 26a and the third lower electrode pattern 28a to fill the hole 20. The fourth lower electrode layer may be etched by an etch back process until the mold layer 14 may be exposed to form a fourth lower electrode pattern 29 filling the hole 20.

The fourth lower electrode pattern 29 may include a material substantially the same as a material of the third lower electrode pattern 28a. Accordingly, the third and fourth lower electrode patterns 28a and 29 may be merged into one electrode pattern.

Thereafter, the capacitor shown in FIG. 3 may be formed by performing substantially the same processes as described with reference to FIGS. 11 to 13.

FIG. 16 is a cross-sectional view illustrating a capacitor in accordance with some example embodiments.

The capacitor shown in FIG. 16 may be the same or substantially the same as the capacitor shown in FIGS. 1 and 2, except that the lower electrode structure has no first lower electrode pattern. Therefore, duplicate descriptions are omitted and only the lower electrode structure is mainly described.

Referring to FIG. 16, the lower electrode structure 30b may include a seed layer pattern 24b, a second lower electrode pattern 26a including the second material, and a third lower electrode pattern 28a including the first material.

The seed layer pattern 24b may be formed on a bottom of a hole included in the mold layer. The second lower electrode pattern 26a may be formed along an upper surface of the seed layer pattern 24b and a sidewall of the hole included in the mold layer. The second lower electrode pattern 26a may have a cylindrical shape. The third lower electrode pattern 28a may be formed on the second lower electrode pattern 26a, and may completely fill a space of the second lower electrode pattern 26a.

Accordingly, the second lower electrode pattern 26a may be exposed on the outer wall of the lower electrode structure 30b. The second material may be exposed on an outer wall of the lower electrode structure 30b.

The capacitor shown in FIG. 16 may be manufactured as follows.

First, the process described with reference to FIGS. 4 and 5 may be performed. Thereafter, the processes described with reference to FIGS. 8 to 13 may be performed without performing the process for forming the first lower electrode pattern. Thus, the capacitor shown in FIG. 16 may be formed.

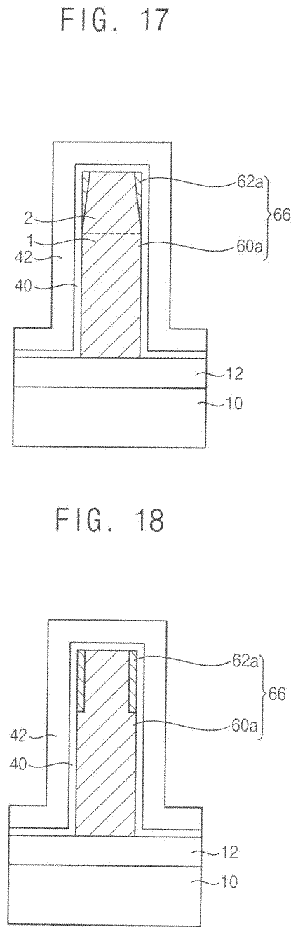

FIG. 17 is a cross-sectional view illustrating a capacitor in accordance with some example embodiments. FIG. 18 is a cross-sectional view illustrating a capacitor in accordance with some example embodiments.

Referring to FIG. 17, the capacitor may include a lower electrode structure 66, a dielectric layer 40 and an upper electrode 42.

The lower electrode structure 66 may include a first lower electrode pattern 60a including the first material and a second lower electrode pattern 62a including the second material. The lower electrode structure 66 may be formed in a hole formed in the mold layer, and thus the lower electrode structure 66 may have a shape the same or substantially the same as a shape of the hole. The first and second materials may be the same or substantially the same as the first and second materials described with reference to FIGS. 1 and 2, respectively.

In the lower electrode structure 66, the first lower electrode pattern 60a may have a pillar shape. The first lower electrode pattern 60a may include a first portion 1 and a second portion 2. The first portion 1 may be a sidewall portion on which the second lower electrode pattern 62a is not formed, and the second portion 2 may be a sidewall portion on which the second lower electrode pattern 62a is formed. The first portion 1 may be a lower portion and a middle portion of the first lower electrode pattern 60a, and the second portion 2 may be an upper portion of the first lower electrode pattern 60a. A width of the first portion 1 of the first lower electrode pattern 60a may be greater than a width of the second portion 2 of the second lower electrode pattern 62a.

The second lower electrode pattern 62a may be formed on an upper sidewall of the hole. The second lower electrode pattern 62a may be formed on a sidewall of the second portion 2 of the first lower electrode pattern 60a.

In some example embodiments, as shown in FIG. 17, the second lower electrode pattern 62a may have a different thickness depending on a positions thereof. For example, a thickness of the second lower electrode pattern 62a may be decreased from top to bottom thereof.

In some example embodiments, as shown in FIG. 18, the second lower electrode pattern 62a may have a uniform thickness depending on a positions thereof.

Accordingly, the first lower electrode pattern 60a and the second lower electrode pattern 62a may be exposed on the outer wall of the lower electrode structure 66. That is, the first material and the second material may be exposed on the outer wall of the lower electrode structure 66. Particularly, the second lower electrode pattern 62a including the second material may be exposed on the upper sidewall of the lower electrode structure 66.

The lower electrode structure 66 may have a sidewall profile the same or substantially the same as a sidewall profile of the hole. Accordingly, the sidewall of the lower electrode structure 66 may not have a protruding portion or a recessed portion. For example, the sidewall of the lower electrode structure 66 may not protrude at a portion for forming the second lower electrode pattern 62a. Meanwhile, a width of the second portion 2 of the first lower electrode pattern 60a may be less than a width of the first portion 1 of the first lower electrode pattern 60a. The width of the second portion 2 of the first lower electrode pattern 60a may vary according to the thickness of the second lower electrode pattern 62a. As the thickness of the second lower electrode pattern 62a increases, the width of the second portion 2 of the first lower electrode pattern 60a may decrease. In addition, the width of the second portion 2 of the first lower electrode pattern 60a may be the same depending on the positions thereof. Alternatively, the width of the second portion 2 of the first lower electrode pattern 60a may be different depending on the positions thereof.

A position of the second lower electrode pattern 62a including the second material may not be limited to the upper portion of the lower electrode structure 66. That is, the position of the second lower electrode pattern 62a including the second material may be variously changed.

FIG. 19 is a cross-sectional view illustrating a capacitor in accordance with some example embodiments.

The capacitor shown in FIG. 19 may be the same as the capacitor shown in FIG. 18 except that the second lower electrode pattern 62a is positioned on a lower sidewall of the lower electrode structure 66.

That is, the second lower electrode pattern 62a may be positioned on the lower sidewall of the first lower electrode pattern 60a. The second lower electrode pattern 62a may have a uniform thickness, or may have a different thickness depending on the positions thereof.

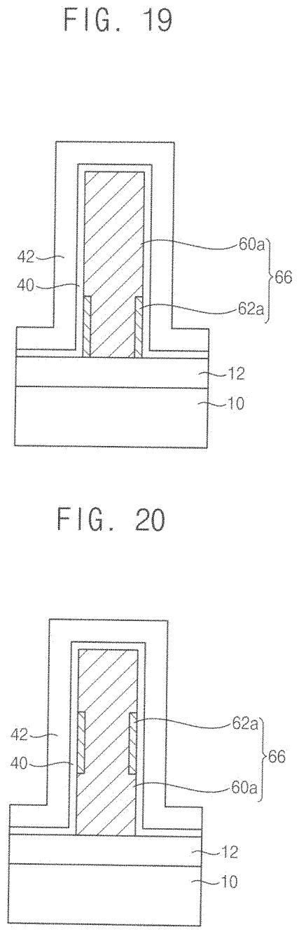

FIG. 20 is a cross-sectional view illustrating a capacitor according to some example embodiments.

The capacitor shown in FIG. 20 is the same as the capacitor shown in FIG. 18 except that the second lower electrode pattern 62a may be positioned on a middle sidewall of the lower electrode structure 66.

That is, the second lower electrode pattern 62a may be positioned on a sidewall of a middle portion of the first lower electrode pattern 60a. The second lower electrode pattern 62a may be formed to have a uniform thickness or to have a different thickness depending on a position thereof.

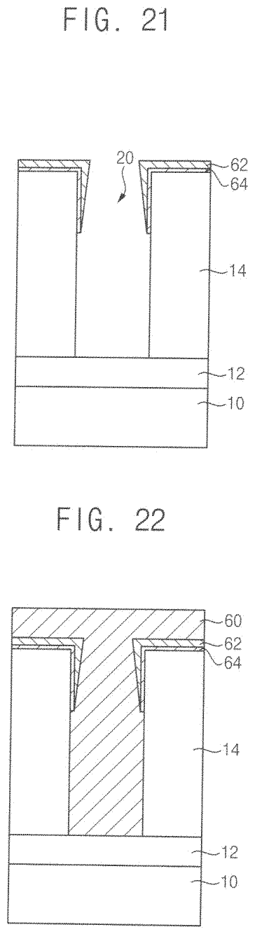

FIGS. 21 to 24 are cross-sectional views for illustrating a method of manufacturing a capacitor in accordance with some example embodiments.

First, the process described with reference to FIG. 4 may be performed.

Referring to FIG. 21, a seed layer 64 may be formed on an upper surface of the mold layer 14 and the upper sidewall of the hole 20. The seed layer 64 may include a metal nitride. For example, the seed layer 64 may include titanium nitride (TiN). The seed layer 64 may serve as an adhesive layer for forming the second lower electrode layer 62.

The seed layer 64 may be formed by a deposition process having a poor step coverage characteristic. For example, the seed layer 64 may be formed by a physical vapor deposition process.

In some example embodiments, the seed layer 64 formed on the upper sidewall of the hole 20 may have a different thickness depending on the positions thereof. For example, in the seed layer 64, a thickness of the seed layer 64 may decrease from an upper portion to a lower portion of the hole 20.

Thereafter, a second lower electrode layer 62 including the second material may be selectively formed on the seed layer 64. The second lower electrode layer 62 may be selectively deposited only on the seed layer 64. Accordingly, the second lower electrode layer 62 may be formed only on the upper sidewall of the hole 20.

In some example embodiments, the second lower electrode layer 62 may be formed by an atomic layer deposition process.

Referring to FIG. 22, a first lower electrode layer 60 including the first material may be formed on the second lower electrode layer 62 to fill the hole 20.

In some example embodiments, the first lower electrode layer 60 may be formed by performing a physical vapor deposition (PVD), a chemical vapor deposition (CVD), or an atomic layer deposition (ALD) process.

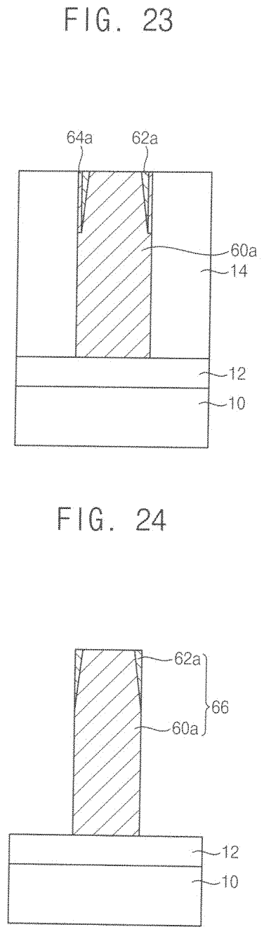

Referring to FIG. 23, upper portions of the first lower electrode layer 60, the seed layer 64 and the second lower electrode layer 62 formed on the upper surface of the mold layer 14 may be removed by an etch-back process. Accordingly, the first lower electrode pattern 60a, the seed layer pattern 64a, and the second lower electrode pattern 62a may be formed to fill the hole 20.

Referring to FIG. 24, the mold layer 14 may be removed. The removing process of the mold layer 14 may include an isotropic etching process.

In the removing process, the seed layer pattern 64a formed on the sidewall of the hole 20 may be removed together to expose an outer wall of the second lower electrode pattern 62a. In the removing process, a portion of the outer wall of the first lower electrode pattern 60a may be slightly removed. Accordingly, the lower electrode structure 66 including the first lower electrode pattern 60a and the second lower electrode pattern 62a may be formed. The first lower electrode pattern 60a and the second lower electrode pattern 62a may be exposed at an outer wall of the lower electrode structure 66.

Thereafter, the same processes as described with reference to FIGS. 12 and 13 may be performed to form a dielectric layer and an upper electrode. Accordingly, the capacitor shown in FIG. 17 may be manufactured.

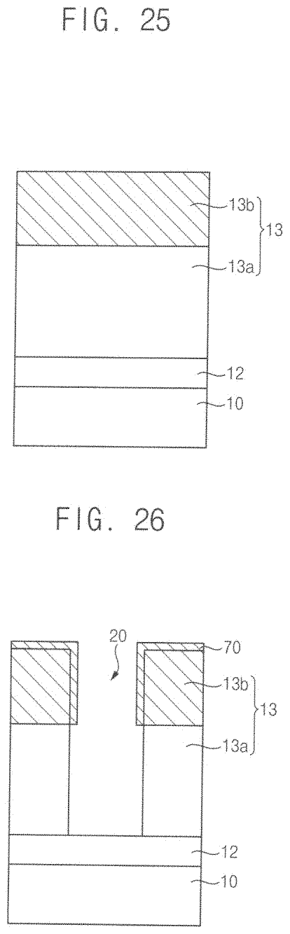

FIGS. 25 to 28 are cross-sectional views for illustrating a method of manufacturing a capacitor in accordance with some example embodiments.

Referring to FIG. 25, the lower structure 12 may be formed on the substrate 10.

A mold layer structure 13 including a first mold layer 13a and a second mold layer 13b may be formed on the lower structure 12. The first mold layer 13a may include an insulation material that inhibits or prevents a second lower electrode layer from being deposited on a surface of the first mold layer 13a in a subsequent process. Meanwhile, the second mold layer 13b may include an insulation material in which the second lower electrode layer may be selectively deposited on a surface of the second mold layer 13b. The second mold layer 13b may include nitride, e.g., silicon nitride. The first mold layer 13a may include, e.g., silicon oxide.

The second mold layer 13b may be positioned at a region for forming the second lower electrode pattern. In some example embodiments, as illustrated, the second mold layer 13b may be formed on the first mold layer 13a, and in this case, the second lower electrode pattern may be formed on an upper sidewall of the lower electrode structure.

Referring to FIG. 26, a portion of the mold layer structure 13 may be etched to form a hole 20 passing through the mold layer structure 13.

A second lower electrode layer 70 including the second material may be selectively deposited on an upper surface of the second mold layer 13b and an upper sidewall of the hole 20 exposing the second mold layer 13b.

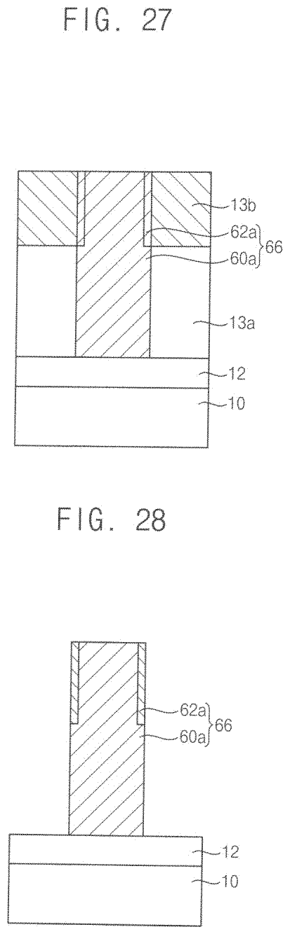

Referring to FIG. 27, a first lower electrode layer including the first material may be formed to fill the hole 20.

Thereafter, upper portions of the first lower electrode layer and the second lower electrode layer formed on the upper surface of the mold layer structure 13 may be removed by an etch-back process. Accordingly, the lower electrode structure 66 including the first lower electrode pattern 60a and the second lower electrode pattern 62a may be formed in the hole 20.

As such, the second lower electrode pattern 62a may be formed on the upper sidewall of the first lower electrode pattern 60a.

Referring to FIG. 28, the mold layer structure 13 may be removed. The removing process of the mold layer structure 13 may include an isotropic etching process.

Thereafter, the same or substantially the same processes as described with reference to FIGS. 12 and 13 may be performed to form the dielectric layer 40 and the upper electrode 42 as shown in FIG. 18. Accordingly, the capacitor shown in FIG. 18 may be manufactured.

Meanwhile, as a position of the second mold layer in the mold layer structure is changed, a position of the second lower electrode pattern may be changed.

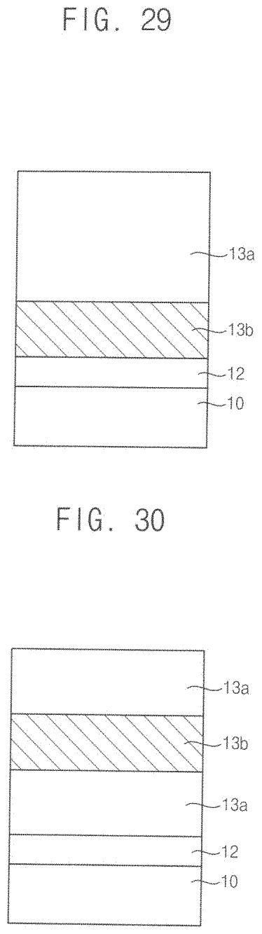

FIG. 29 is a cross-sectional view for illustrating a method of manufacturing a capacitor in accordance with some example embodiments.

Referring to FIG. 29, the lower structure 12 may be formed on the substrate 10.

First, a second mold layer 13b may be formed on the lower structure 12, and then a first mold layer 13a may be formed on the second mold layer 13b to form a mold layer structure. In this case, the second lower electrode layer may be selectively deposited on a region for forming the second mold layer 13b. Accordingly, the second lower electrode pattern 62a (e.g., refer to FIG. 19) may be formed on a lower sidewall of the lower electrode structure.

After forming the mold structure, the same or substantially the same processes as described with reference to FIGS. 26 to 28 may be performed to manufacture the capacitor shown in FIG. 19.

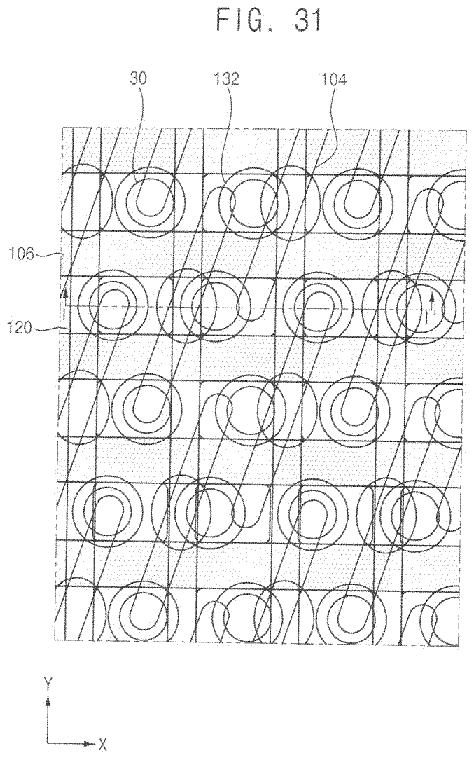

FIG. 30 is a cross-sectional view for illustrating a method of manufacturing a capacitor in accordance with some example embodiments.

Referring to FIG. 30, the lower structure 12 may be formed on the substrate 10. A first mold layer 13a may be formed on the lower structure 12. A second mold layer 13b may be formed on the first mold layer, and then a first mold layer 13a may be formed on the second mold layer 13b. Accordingly, a mold layer structure may include the first mold layer 13a, the second mold layer 13b, and the first mold layer 13a are stacked. In some example embodiments, the second lower electrode layer may be selectively deposited on a region for forming the second mold layer, and thus the second lower electrode pattern 62a (e.g., refer to FIG. 20) may be formed on a sidewall of a middle portion of the lower electrode structure.

After forming the mold structure, the same or substantially the same processes as described with reference to FIGS. 26 to 28 may be performed to manufacture the capacitor shown in FIG. 20.

Hereinafter, a DRAM device including a cell capacitor is described.

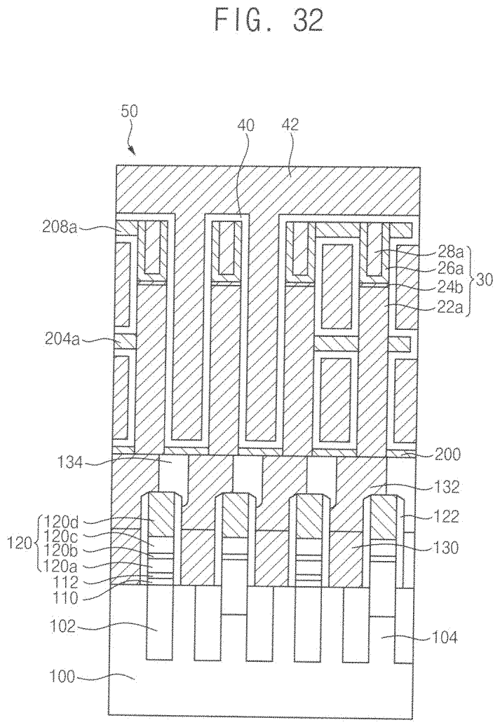

FIG. 31 is a plan view illustrating a layout of a DRAM device in accordance with some example embodiments. FIG. 32 is a cross-sectional view of a DRAM device in accordance with some example embodiments.

In order to avoid complication of the drawings, a structure on the lower electrode in the cell capacitor is not shown in FIG. 31. FIG. 32 is a cross-sectional view taken along the line I-I′ of FIG. 31.

Referring to FIGS. 31 and 32, the DRAM device may be formed on a substrate 100.

The substrate 100 may be a wafer including silicon, germanium, silicon-germanium, or a III-V compound such as GaP, GaAs, or GaSb, but example embodiments are not limited thereto. In some example embodiments, the substrate 100 may be a silicon-on-insulator (SOI) wafer or a germanium-on-insulator (GOI) wafer.

The DRAM device may include selection transistors, cell capacitors, and a bit line structure 120. A unit memory cell of the DRAM device may include one selection transistor and one cell capacitor.

An isolation layer 102 may be formed on the substrate 100. An upper portion of the substrate 100 between the isolation layers 102 may be defined as an active region 104.

A gate trench may be formed at the substrate 100. The gate trench may extend in a first direction X parallel or substantially parallel to an upper surface of the substrate 100. A gate structure 106 may be formed in the gate trench.

In some example embodiments, the gate structure 106 may include a gate insulation layer, a gate electrode, and a capping insulation pattern. The gate structure 106 may extend in the first direction X. A plurality of the gate structures 106 may be formed in a second direction Y parallel or substantially parallel to the upper surface of the substrate 100 and perpendicular or substantially perpendicular to the first direction X.

First and second impurity regions (not shown) serving as source/drain regions may be formed at the active region 104 between the gate structures 106. The gate structure 106 and the first and second impurity regions may serve as each of the selection transistors.

A first insulation pattern 110 and a second insulation pattern 112 may be stacked on the active region 104, the isolation layer 102 and the gate structure 106. For example, the first insulation pattern 110 may include an oxide such as silicon oxide, and the second insulation pattern 112 may include a nitride such as silicon nitride.

A recess may be included in a portion of the substrate 100 on which the first insulation pattern 110 and the second insulation pattern 112 are not formed. A top surface of the first impurity region may be exposed on a bottom surface of the recess.

The bit line structure 120 may be formed on the second insulation pattern 112 and the recess. The bit line structure 120 may include a conductive pattern 120a, a barrier metal pattern 120b, a metal pattern 120c, and a hard mask pattern 120d. The conductive pattern 120a may include, e.g., polysilicon doped with impurities. The bit line structure 120 may extend in the second direction. A plurality of bit line structures may be arranged in the first direction. In some example embodiments, a spacer 122 may be formed on a sidewall of the bit line structure 120. Although not shown, the spacer may have a structure in which a plurality of spacers are laterally stacked.

A first insulating interlayer (not shown) may be formed to fill a space between the bit line structures 120.

A contact plug 130 and a landing pad 132 may contact the second impurity region through the first insulating interlayer, the second insulation pattern 112 and the first insulation pattern 110. The contact plug 130 may be between the bit line structures 120. The landing pad 132 may be formed on the contact plug 130. An insulation pattern 134 may be between the landing pads 132.

An etch stop layer 200 may be formed on the landing pad 132, the insulation pattern 134 and the first insulating interlayer. A cell capacitor 50 may contact the landing pad 132 through the etch stop layer 200.

The etch stop layer 200 may include, e.g., silicon nitride, silicon oxynitride, or the like.

The cell capacitor 50 may include a lower electrode structure 30, a dielectric layer 40 and an upper electrode 42. In addition, a lower support layer pattern 204a and an upper support layer pattern 208a may be formed on a sidewall of the lower electrode structure 30. A lower surface of the lower electrode structure 30 may contact the landing pad 132.

The dielectric layer 40 may be conformally formed along an outer surfaces of the lower electrode structure 30, the lower support layer pattern 204a and the upper support layer pattern 208a. The upper electrode 42 may be formed on the dielectric layer 40.

The lower electrode structure 30 may have the same or substantially the same shape as one of the lower electrode structures of the capacitor in accordance with some example embodiments. That is, the cell capacitor may have the same shape as one of the capacitors shown in FIGS. 1, 2, 3, and 16 to 20.

FIG. 32 shows the lower electrode structure 30 shown in FIG. 1, which is described with reference.

As shown in FIG. 32, the lower electrode structure 30 may include the first lower electrode pattern 22a including the first material, the seed layer pattern 24b, and the second lower electrode pattern including the second material and the third lower electrode pattern 28a including the first material.

Each of the lower support layer pattern 204a and the upper support layer pattern 208a may be connected to an outer wall of the lower electrode structure 30 to each other. Thus, each of the lower support layer pattern 204a and the upper support layer pattern 208a may support the outer wall of the lower electrode structure 30 to each other. The lower support layer pattern 204a and the upper support layer pattern 208a may include an insulation material, e.g., silicon nitride or silicon oxynitride. In some example embodiments, only one among the lower support layer pattern and the upper support layer pattern may be formed on the outer wall of the lower electrode structure 30, or both of the lower support layer pattern and the upper support layer pattern may not be formed.

The second lower electrode pattern 26a including the second material may be exposed on at least the outer wall of the lower electrode structure 30. Accordingly, the cell capacitor may have a high capacitance, and may be prevented from increasing of bending stress.

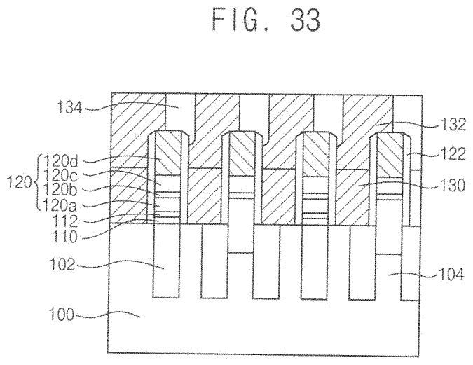

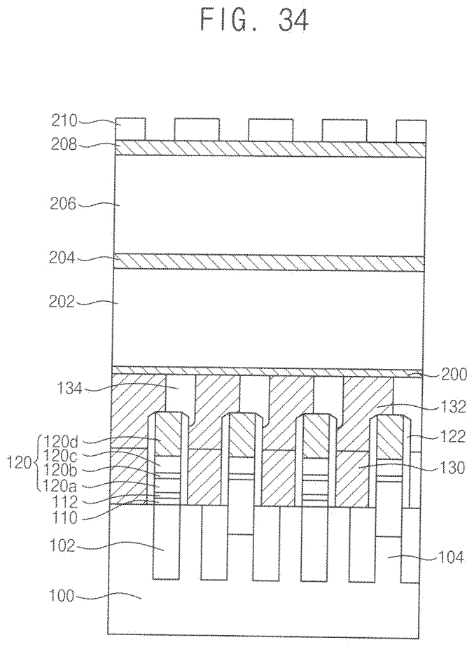

FIGS. 33 to 37 are a cross-sectional view for illustrating a method of manufacturing a capacitor in accordance with some example embodiments.

Referring to FIG. 33, an isolation layer 102 may be formed by performing a shallow trench isolation (STI) process on the substrate 100. Accordingly, the substrate 100 may be divided into an isolation region in which the isolation layer 102 is formed and an active region 104 between the isolation layer 102.

Upper portions of the substrate 100 and the isolation layer 102 may be etched to form a gate trench (not shown) extending in the first direction. A gate structure (not shown) may be formed in the gate trench. First and second impurity regions (not shown) may be formed at active regions adjacent to both sides of the gate structure.

A first insulation pattern 110 and a second insulation pattern 112 may be formed on the active region, the isolation layer 102 and the gate structure. A recess (not shown) may be formed at a substrate on which the first insulation pattern 110 and the second insulation pattern 112 may not be formed. An upper surface of the first impurity region may be exposed on a bottom of the recess.

A bit line structure 120 extending in the second direction may be formed on the second insulation pattern 112 and the recess. The bit line structure 120 may have a stacked structure of a conductive pattern 120a, a barrier metal pattern 120b, a metal pattern 120c, and a hard mask pattern 120d. In some example embodiments, a spacer 122 may be formed on a sidewall of the bit line structure 120.

A first insulating interlayer (not shown) may be formed to cover the bit line structures 120.

A portion of the first insulating interlayer between the bit line structures 120 may be etched to form a contact hole exposing the second impurity region of the substrate. A contact plug 130 and a landing pad 132 may be formed to fill the contact hole. An insulation pattern 134 may be formed between the landing pads 132.

Referring to FIG. 34, an etch stop layer 200 may be formed on the first insulating interlayer, the landing pad 132 and the insulation pattern 134. The etch stop layer 200 may include, e.g., silicon nitride, silicon oxynitride, or the like.

A lower mold layer 202, a lower support layer 204, an upper mold layer 206 and an upper support layer 208 may be sequentially stacked on the etch stop layer 200. The lower mold layer 202 and the upper mold layer 206 may include a material having an etch selectivity with respect to the lower support layer 204 and the upper support layer 208. For example, the lower mold layer 202 and the upper mold layer 206 may include silicon oxide, and the lower support layer 204 and the upper support layer 208 may include silicon nitride.

A capacitor mask pattern 210 may be formed on the upper support layer 208. The capacitor mask pattern 210 may include holes at positions for forming the lower electrode structures. The holes may be arranged in a honeycomb structure. The capacitor mask pattern 210 may include amorphous carbon or polysilicon.

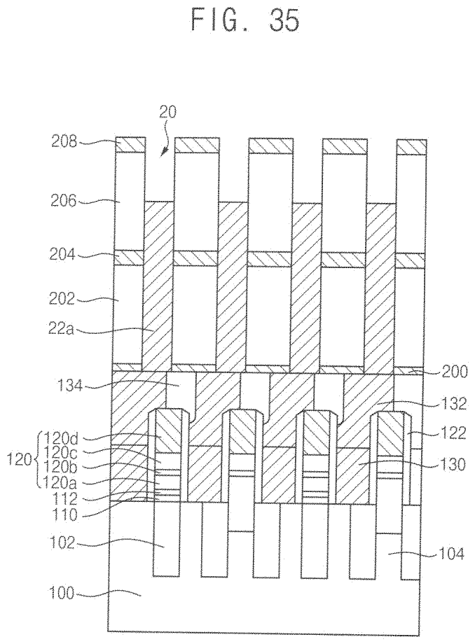

Referring to FIG. 35, an upper support layer 208, an upper mold layer 206, a lower support layer 204, a lower mold layer 202 and an etch stop layer may be etched using the capacitor mask pattern 210 as an etch mask to form holes 20. The etching process may include an anisotropic etching process. Each of the holes 20 may expose an upper surface of the landing pad 132.

A first lower electrode layer may be formed on the upper support layer 208 to completely fill the holes. The first lower electrode layer may include a first material. The first material may include a metal or a metal nitride having a low bending stress. In some example embodiments, the first lower electrode layer may include titanium nitride (TiN) or titanium (Ti).

Thereafter, the upper portion of the first lower electrode layer may be removed to form a first lower electrode pattern 22a at an inner portion of the hole 20. The removing process may include an etch-back process.

The process for forming the first lower electrode pattern 22a may be substantially the same as described with reference to FIGS. 5 and 6.

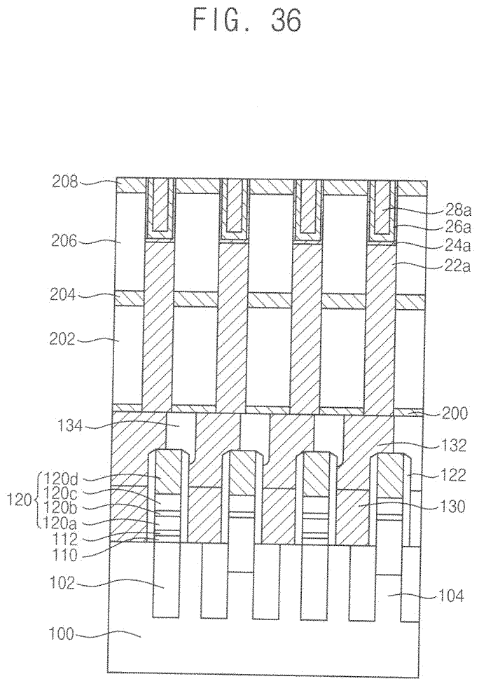

Referring to FIG. 36, a seed layer may be conformally formed on the upper sidewall of the hole 20, the first lower electrode pattern 22a and the upper support layer 208. A second lower electrode layer may be conformally formed on the seed layer. A third lower electrode layer may be formed on the second lower electrode layer to completely fill the hole 20.

In some example embodiments, the seed layer may include a metal nitride. The second lower electrode layer may be selectively deposited on the seed layer including the metal nitride.

For example, the seed layer may include titanium nitride (TiN). The second lower electrode layer may include a second material different from the first material. When the second material is used as the lower electrode, the capacitance of the capacitor may increase compared to a case where the first material is used as the lower electrode. The second material may have a bending stress higher than a bending stress of the first material.

In some example embodiments, the second material may include, e.g., niobium nitride, niobium, indium tin oxide (ITO), or ruthenium (Ru).

The third lower electrode layer may include the first material. In some example embodiments, the third lower electrode layer may include, e.g., titanium nitride (TiN) or titanium (Ti).

Processes for forming the seed layer, the second lower electrode layer and the third lower electrode layer may be substantially the same as those described with reference to FIGS. 8 and 9.

Thereafter, upper portions of the third lower electrode layer and the second lower electrode layer formed on an upper surface of the upper support layer 208 may be removed by an etch-back process. Accordingly, a preliminary seed layer pattern 24a, a second lower electrode pattern 26a, and a third lower electrode pattern 28a may be formed on the first lower electrode pattern 22a to fill the hole 20.

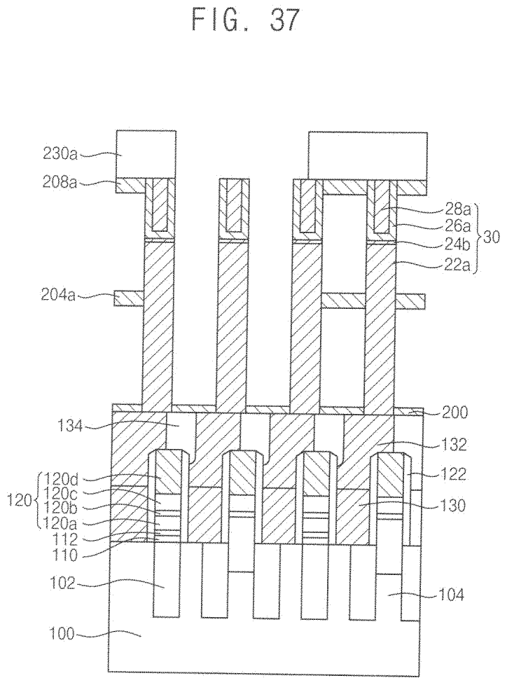

Referring to FIG. 37, a first mask pattern may be formed on the upper support layer 208, the preliminary seed layer pattern 24a, the second lower electrode pattern 26a and the third lower electrode pattern 28a. The upper support layer 208 may be etched using the first mask pattern as an etch mask to form an upper support layer pattern 208a. The etching process may include an anisotropic etching process, e.g., a dry etching process. The upper support layer pattern 208a may include first openings.

The upper mold layer 206 may be removed. The removing process may include an isotropic etching process, e.g., a wet etching process.

The lower support layer 204 may be etched using the first mask pattern 230a to form a lower support layer pattern 204a. The etching process may include an anisotropic etching process, e.g., a dry etching process.

The lower support layer pattern 204a may have a shape substantially the same as a shape of the upper support layer pattern 208a. The lower support layer pattern 204a may include second openings. The second openings may be located at the same position as the first openings.

The lower mold layer 202 may be removed. The removing process may include an isotropic etching process, e.g., a wet etching process. The first mask pattern 230a may be removed.

The lower support layer pattern 204a and the upper support layer pattern 208a for supporting the lower electrode structure 30 may be formed by performing the above process. During the removing process, the preliminary seed layer pattern 24a exposed on the sidewall of the upper mold layer 206 may be removed together to expose an outer wall of the second lower electrode pattern 26a to form a lower electrode structure 30. The lower electrode structure may include the first lower electrode pattern 22a, the seed layer pattern 24b, the second lower electrode pattern 26a and the third lower electrode pattern 28a.

Referring to FIG. 32 again, the first mask pattern 230a may be removed.

A dielectric layer 40 may be formed to have a uniform thickness on the sidewall and upper surface of the lower electrode structure 30, the lower support layer pattern 204a, the upper support layer pattern 208a and the etch stop layer 200. The dielectric layer 40 may include a metal oxide having a high dielectric constant. For example, the dielectric layer 40 may include HfO2, ZrO2, TiO2, TaO, or La2O3, but example embodiments are not limited thereto.

An upper electrode 42 may be formed on the dielectric layer 40.

The upper electrode 42 may be, e.g., titanium nitride (TiN), titanium (Ti), tantalum (Ta), tantalum nitride (TaN), ruthenium (Ru), tungsten, tungsten nitride, Nb, NbN, indium tin oxide (ITO), Ta doped SnO2, Nb doped SnO2, Sb doped SnO2, or V doped SnO2, but example embodiments are not limited thereto.

A DRAM device may be manufactured by the above process. In the DRAM device, the first material for increasing the capacitance of the cell capacitor, may be exposed on an outer surface of the lower electrode structure of the cell capacitor, so that the capacitor may have a high capacitance.

In some example embodiments, the cell capacitor included in the DRAM device may be any one of the capacitors shown in FIGS. 2, 3, and 16 to 20. The DRAM device may be manufactured by forming the etch stop layer and performing process for forming the capacitor according to the example embodiments, after performing the process described with reference to FIG. 29.

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof

What is claimed is:

1. A capacitor, comprising:
a first lower electrode pattern including a first material including a metal;
a second lower electrode pattern including a second material different from the first material, wherein the first material and the second material are exposed on an outer sidewall of a lower electrode structure having a pillar shape;
a dielectric layer on the lower electrode structure; and
an upper electrode on the dielectric layer.

2. The capacitor of claim 1, wherein
the first material includes a metal or a metal nitride, and
the metal or the metal nitride has a bending stress lower than a bending stress of the second material.

3. The capacitor of claim 1, wherein a capacitance at a contacting portion of the second material and the dielectric layer is higher than a capacitance at a contacting portion of the first material and the dielectric layer.

4. The capacitor of claim 1, wherein
the first material includes titanium nitride (TiN) or titanium (Ti), and
the second material includes niobium nitride, niobium, indium tin oxide (ITO), or ruthenium (Ru).

5. The capacitor of claim 1, wherein in the lower electrode structure, a volume of the first material is greater than a volume of the second material.

6. The capacitor of claim 1, wherein
the first lower electrode pattern has a pillar shape,
the second lower electrode pattern is on an upper surface of the first lower electrode pattern, and
the second lower electrode pattern has a cylindrical shape.

7. The capacitor of claim 6, wherein an outer sidewall of the second lower electrode pattern is exposed on a portion of an outer wall of the lower electrode structure.

8. The capacitor of claim 6, wherein
the lower electrode structure further includes a third lower electrode pattern on the second lower electrode pattern, and
the third lower electrode pattern includes the first material filling an inner portion of the second lower electrode pattern.

9. The capacitor of claim 8, wherein
the lower electrode structure further includes a fourth lower electrode pattern on the second lower electrode pattern and the third lower electrode pattern, and
the fourth lower electrode pattern includes the first material.

10. The capacitor of claim 6, further comprising a seed layer pattern between the first lower electrode pattern and the second lower electrode pattern in the lower electrode structure.

11. The capacitor of claim 1, wherein
the first lower electrode pattern has a pillar shape, and
the second lower electrode pattern is on a portion of an outer wall of the first lower electrode pattern.

12. The capacitor of claim 11, wherein
the first lower electrode pattern includes a first portion including an outer wall on which the second lower electrode pattern is not formed, and a second portion including an outer wall on which the second lower electrode pattern is formed, and
an inner width of the second portion is less than an inner width of the first portion.

13. A capacitor, comprising:
a lower electrode structure including a first material, a second material, a first lower electrode pattern, a second lower electrode pattern, and a third lower electrode pattern, wherein the second material is different from the first material, the first material and the second material are exposed on an outer sidewall, and the lower electrode structure has a pillar shape;
a dielectric layer on the lower electrode structure; and
an upper electrode on the dielectric layer,
wherein the first lower electrode pattern includes the first material, and the first lower electrode pattern has a pillar shape,
wherein the second lower electrode pattern includes the second material, the second lower electrode pattern is on an upper surface of the first lower electrode pattern, and the second lower electrode pattern has a cylindrical shape, and
wherein the third lower electrode pattern includes the first material, the third lower electrode pattern is on the second lower electrode pattern, and the third lower electrode pattern fills an inner portion of the second lower electrode pattern.

14. The capacitor of claim 13, wherein
the first material includes a metal or a metal nitride, and
the first material or the metal nitride has a bending stress lower than a bending stress of the second material.

15. The capacitor of claim 13, wherein a capacitance at a contacting portion of the second material and the dielectric layer is higher than a capacitance at a contacting portion of the first material and the dielectric layer.

16. The capacitor of claim 13, wherein
the first material includes titanium nitride (TiN) or titanium (Ti), and
the second material includes niobium nitride, niobium, indium tin oxide (ITO), or ruthenium (Ru).

17. The capacitor of claim 13, wherein in the lower electrode structure, a volume of the first material is greater than a volume of the second material.

18. A DRAM device, comprising:
a cell transistor on a substrate, the cell transistor including a gate structure, a first impurity region, and a second impurity region;
a bit line structure electrically connected to the first impurity region; and
a cell capacitor disposed on the bit line structure, the cell capacitor electrically connected to the second impurity region, wherein the cell capacitor includes a lower electrode structure including a first lower electrode pattern and a second lower electrode pattern, the cell capacitor includes a dielectric layer on the lower electrode structure, and the cell capacitor includes an upper electrode on the dielectric layer, and wherein the second lower electrode pattern includes a material having a bending stress greater than a bending strength of the first lower electrode pattern,
wherein at least a portion of the first lower electrode pattern and the second lower electrode pattern is exposed on an outer wall of the lower electrode structure.

19. The DRAM device of claim 18, wherein a capacitance at a contacting portion of the second lower electrode pattern and the dielectric layer is higher than a capacitance at a contacting portion of the first lower electrode pattern and the dielectric layer.

20. The DRAM device of claim 18, wherein the lower electrode structure has a pillar shape.
